(19) United States
(12) Patent Application Publication
(10) Pub. No.: US 2021/0351228 A1
(43) Pub. Date: Nov. 11, 2021

(54) LIGHT-EMITTING DEVICE, AND METHOD FOR PRODUCING SAME

(71) Applicant: OSRAM OLED GmbH, Regensburg (DE)

(72) Inventors: Meik WECKBECKER, Thalmassing (DE); Vincent GROLIER, München (DE); Philipp KREUTER, Regensburg (DE); Florian BOESL, Regensburg (DE); Michael JOBST, Wiesenfelden (DE)

(21) Appl. No.: 17/277,894

(22) PCT Filed: Dec. 7, 2018
(86) PCT No.: PCT/EP2018/083935

§ 371 Date: Mar. 19, 2021

(30) Foreign Application Priority Data
Sep. 19, 2018 (DE) 10 2018 215 951.3

(51) Int. Cl. H01L 27/15; H01L 33/62; H01L 33/60; H01L 25/11; H01L 33/00

(52) U.S. Cl. CPC H01L 27/156; H01L 33/62; H01L 33/60; H01L 2933/0066; H01L 33/005; H01L 2933/0058; H01L 25/117

(57) ABSTRACT

A light-emitting device includes a multiplicity of light-emitting modules arranged on a first substrate. Each light-emitting module of the multiplicity of light-emitting modules includes a multiplicity of light-emitting components arranged on a second substrate. The second substrate is electrically connected to the first substrate, and includes a common primary lens for the multiplicity of light-emitting components.

The invention relates to a light-emitting device and to a method for producing the same.

A conventional light-emitting device comprises a multiplicity of light-emitting diodes (LEDs) arranged in a matrix pattern or in a disordered manner directly on a circuit board. The circuit board usually contains at least some of the electronic components of the driver for driving the LEDs. A conventional light-emitting device is distinguished by a small number of large LEDs which are arranged with a high packing density and are imaged in the far field by way of a primary optical unit and a split secondary optical unit. The conventional light-emitting device has a high structural depth and engageability, which causes a limited freedom of design. Furthermore, the high packing density has the effect of reducing the size of the primary and secondary optical units, but causes a problem in regard to heat dissipation. Furthermore, adapting the light-emitting device for different applications requires significant changes associated with a high degree of effort and synergistic effects are relatively small in this case.

In order to increase the freedom of design, very small LEDs having a short edge length, for example of 5-100 μm, can be used instead of conventional LEDs. With the use of very small LEDs, however, special materials are required for the circuit board. As an example, a four-layered circuit board layout is required in order to connect a multiplicity of small LEDs to one another on a common circuit board. However, these special materials are expensive and more complex in the production process. As an example, approximately 1000 LEDs are required for a headlight in an automotive application with high beam and low beam. If all the LEDs are mounted on a common circuit board, this can result in a great reduction of the production yield owing to a failure of a few LEDs on the circuit board.

One object of the invention is to increase the freedom for a light-emitting device in terms of layout or design. A further object of the invention may consist in increasing the ease of maintenance of the light-emitting device. A further object of the invention may consist in reducing the production outlay for a light-emitting device, e.g. by increasing the production yield of the light-emitting device. A further object of the invention may consist in reducing the total installation depth of headlights/spotlights. Moreover, one object may be to prevent thermal problems and glare problems from occurring. Alternatively or additionally, it is possible to provide vehicle headlights such that they are simpler in terms of headlight design and/or have more degrees of freedom of design, allowing a plurality of lighting functions.

In accordance with one aspect of the invention, the object is achieved by means of a light-emitting device comprising a multiplicity of light-emitting modules arranged on a first substrate. Each light-emitting module of the multiplicity of light-emitting modules comprises a multiplicity of light-emitting components arranged on a second substrate, wherein the second substrate is electrically connected to the first substrate; and each light-emitting module comprises a common primary lens for the multiplicity of light-emitting components.

The light-emitting components are electrically conductively connected to the second substrate, which is electrically conductively connected to the first substrate, e.g. by way of an electrically conductive connection structure on or within the second substrate, e.g. by means of conductive lines, contact holes (VIAs) and/or plugs, pins, solder pads, etc. That is to say that the light-emitting components are not directly connected to the substrate, e.g. by way of bonded wires.

The common primary lens is a common lens (also referred to as a split primary lens) for the multiplicity of light-emitting components. The common primary lens is configured to optically image the multiplicity of light-emitting components. In other words, the common primary lens is configured such that it refracts the light emitted by the multiplicity of light-emitting components. The common primary lens is the first optical element (apart from an optional reflective layer structure) that optically adjoins the light-emitting components and is configured to shape the light beam emitted by a light-emitting component, for example to deflect it to a common focal point for the light-emitting components of the light-emitting module.

In various embodiments, the light-emitting device is free of secondary optical units for the multiplicity of light-emitting modules. In other words: the light-emitting device in accordance with various embodiments is a light-emitting device without a secondary optical unit for the multiplicity of light-emitting modules and in each case with a common primary lens for the multiplicity of light-emitting components of a light-emitting module. However, the light-emitting device can comprise for the multiplicity of light-emitting components a common, secondary, optical component, for example in the form of a light-transmissive cover in the beam path of the light-emitting components of the multiplicity of light-emitting modules and/or a reflector configured for example peripherally with respect to the multiplicity of light-emitting modules.

In various embodiments, the light-emitting modules are configured only or specifically for a single predefined headlight/spotlight functionality, for example low beam, high beam, etc. The flexibility of the design of the light-emitting device is thus increased by combining different, prefabricated modules.

In the light-emitting device, the light-emitting modules can be arranged in clusters for the respective application-specific requirement or can be distributed over the entire first substrate. This enables a flexible design of the light-emitting device with “functional regions” and a high freedom of design, e.g. for the design of an automotive headlight.

The first substrate can be a cost-effective carrier, e.g. a metal-coated film or a two-layered circuit board, and thus the costs are reduced and the yield of the production method is increased. In particular, the costs of a faulty light-emitting module are relatively low in comparison with a faulty light-emitting device.

The light-emitting device makes it possible that a driver circuit, also referred to as control electronics, for driving the light-emitting components can be arranged independently of the light-emitting components by the use of the light-emitting modules. As an example, the control electronics can be arranged on the first substrate, on which the second substrates are arranged. Alternatively, the control electronics can be integrated on the first and/or second substrate or be disposed externally relative to the first and second substrates.

In various embodiments, the first substrate can comprise the control electronics (driver circuit) and other electronic components. The first substrate can be individualized for the specific application, e.g. for the respective headlight/spotlight design. It is thus possible to provide different first substrates having predefined standardized regions (e.g. solder pads), on which the second substrates can be mounted. Furthermore, the light-emitting device can comprise two or more first substrates. By way of example, a light-emitting device, for example a floodlight, can comprise one or a plurality of first substrates, on which second substrates are arranged. The light-emitting device can also result in reduced cost accounting for the material (e.g. two-layered second substrate instead of a large common four-layered circuit board composed of standard material). Furthermore, the production costs can be low owing to a high yield (fewer components per module) and a large number of modules (reusability in other headlight/spotlight designs).

The specific arrangement of the second substrates on the first substrate is freely selectable and enables a high freedom of design, e.g. for the design of compact front headlights in automotive applications.

Furthermore, it is possible to realize a multiplicity of different arrangement patterns for the light-emitting components on the second substrates. Arrangement patterns can differ for example in the number of light-emitting components per light-emitting module, the interconnection of the light-emitting components and/or the arrangement, for example the number density, of the light-emitting components on the second substrate. By way of example, in an automotive headlight an arrangement pattern required to realize a low beam function is different than the arrangement pattern required to realize a high beam function.

The light-emitting components can be arranged regularly or irregularly on the second substrate in a light-emitting module.

Furthermore, the light-emitting device can make it possible that the control electronics (driver circuit) can be mounted on the first substrate or can be accommodated on a separate circuit board. Furthermore, a small depth can be realized, e.g. for light-emitting devices as headlights/spotlights. Furthermore, the light-emitting device has a good scalability as a result of the modular approach (using the light-emitting modules). Furthermore, the light-emitting device enables a high freedom of design; by way of example, this enables simple exchange of the first substrate and high synergies over the product range.

In various embodiments, a portion of the multiplicity of light-emitting modules, for example one or more groups of light-emitting modules, wherein each group comprises the same type and quantity of light-emitting components, is used to realize one of the individual lighting functions.

In various exemplary embodiments, the light-emitting device comprises 100-1000 small light-emitting components distributed e.g. in a multiplicity of light-emitting modules, each comprising for example approximately 2 to 20 light-emitting components in a sparse array arrangement. In a sparse array arrangement, the light-emitting components have, relative to the first substrate and/or the respective second substrate, an area coverage on the second substrate of less than approximately 5%, for example less than approximately 2.5%, for example less than approximately 1%. The area coverage can be understood such that each light-emitting diode has a basic area, for example on the basis of the shape of a light-emitting diode chip in plan view (emission direction) and the ratio of the sum of the area magnitudes of the individual basic areas of the light-emitting components of an individual light-emitting module to the area magnitude of the surface area of the second substrate of the light-emitting module on which the light-emitting components are arranged.

The light-emitting components can be arranged on the second substrate in each case in a very concentrated manner spatially in one region, such that outside this region the light-emitting module is substantially free of light-emitting components. In other words: a light-emitting module can have a first region, for example spanned by possible matrix positions for light-emitting components, with an area coverage of light-emitting components in the range of, for example, approximately 10% to approximately 50%, or even more. The light-emitting module can additionally have a second region, which is arranged next to the first region or surrounds the latter, with an area coverage of light-emitting components of less than or equal to 10%, for example less than or equal to 5%, for example less than or equal to 1%. Consequently, on average both the second substrate and the first substrate can be sparsely populated with light-emitting components.

Since heat is not generated at one location, but rather is distributed uniformly over a large area, the light-emitting device in accordance with various embodiments can reduce the size (the volume) of the heat sink (for example cooling element). A light-emitting device in accordance with various embodiments thus has a significantly reduced structural depth.

In addition, the common primary lens of the multiplicity of light-emitting components can be different for each lighting function or even within a lighting function. In other words: a plurality of groups of light-emitting components can be provided in the headlight/spotlight in order to realize one or different lighting functions. In a vehicle headlight, for example, the different lighting functions are high beam and low beam, adaptive driving beam (ADB), daytime running light, cornering light, such as steerable beam and/or flashing indicators, position light and/or fog light.

Furthermore, with respect to the lighting functions mentioned above, a brake light function can also be integrated in the headlight. This additional lighting function has the particular advantage that pedestrians or other road users, upon observing the headlight, recognize whether the vehicle is in the process of braking.

Furthermore, a plurality of lighting functions can be realized in a single headlight/spotlight, and a single power supply and control unit (driver circuit) for the headlight/spotlight can thus be sufficient. By way of example, the required wiring of the light-emitting device is simplified in this way.

In accordance with a further aspect of the invention, the object is achieved by providing a method for producing a light-emitting device. The method comprises providing a first substrate and arranging a multiplicity of light-emitting modules on the first substrate. Each light-emitting module of the multiplicity of light-emitting modules comprises a multiplicity of light-emitting components arranged on a second substrate, wherein the second substrate is electrically connected to the first substrate; and comprises a common primary lens for the multiplicity of light-emitting components.

This makes it possible to increase the production yield for the light-emitting device.

Further embodiments are described in the dependent claims.

Embodiments of the invention are illustrated in the figures and are explained in greater detail below. In the drawings:

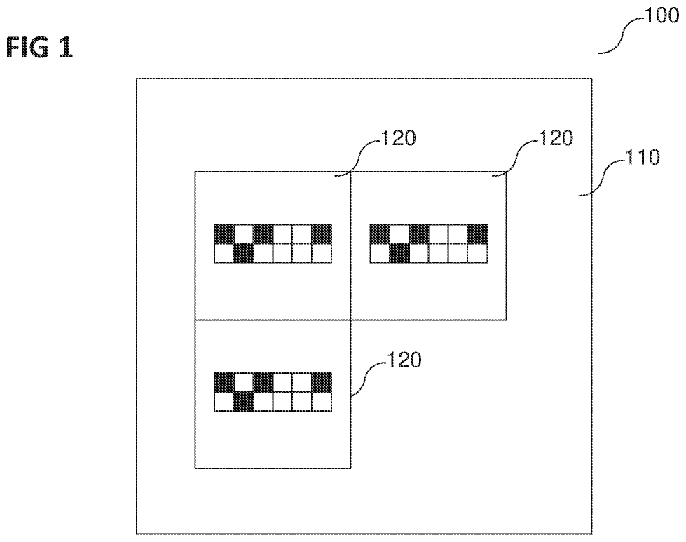

FIG. 1 shows a plan view of a schematic light-emitting device in accordance with various embodiments;

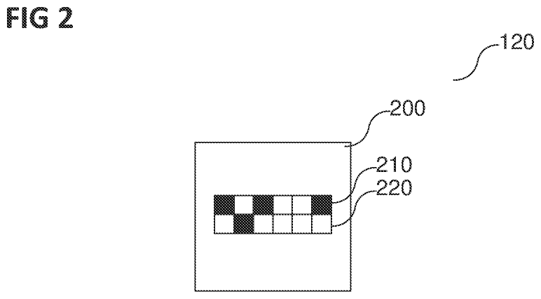

FIG. 2 shows a plan view of a schematic light-emitting module of a multiplicity of light-emitting modules of a light-emitting device in accordance with various embodiments;

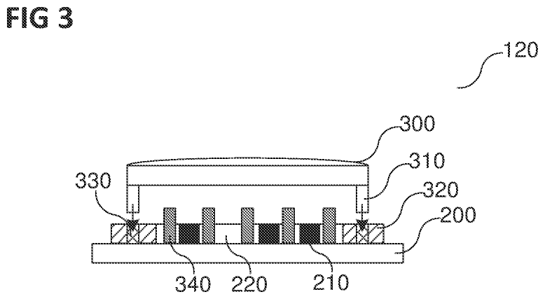

FIG. 3 shows a cross-sectional view of a schematic light-emitting module of a multiplicity of light-emitting modules of a light-emitting device in accordance with various embodiments;

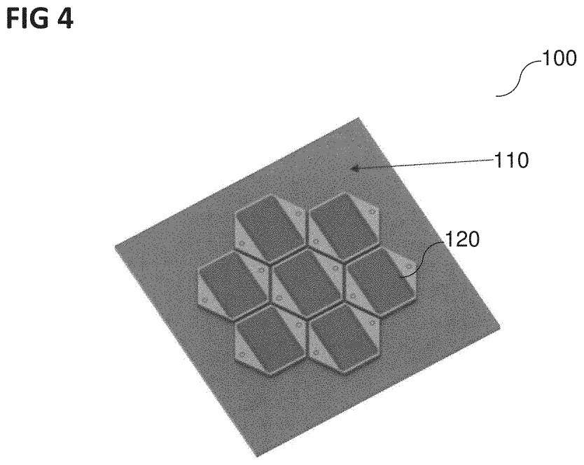

FIG. 4 shows a plan view of a schematic light-emitting device with a multiplicity of light-emitting modules in accordance with various embodiments; and

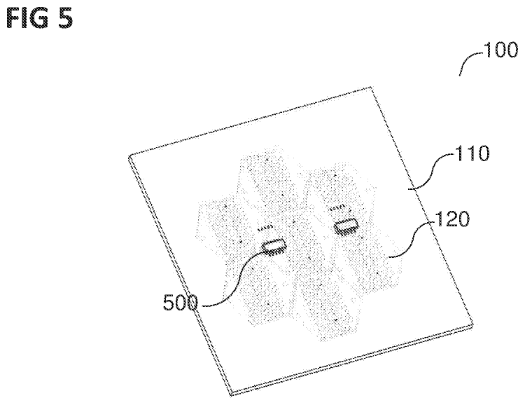

FIG. 5 shows a bottom view of a schematic light-emitting device with a multiplicity of light-emitting modules in accordance with various embodiments.

In the following detailed description, reference is made to the accompanying drawings, which form part of this description and show for illustration purposes specific embodiments in which the invention can be implemented. In this regard, direction terminology such as “at the top”, “at the bottom”, “on top”, “underneath”, “at the front”, “at the back”, etc. is used with respect to the orientation of the figure(s) described.

Since component parts of embodiments can be positioned in a number of different orientations, the direction terminology is illustrative and is not restrictive in any way. It should be understood that other embodiments can be used and structural or logical changes can be made, without departing from the scope of protection of the present invention. It should be understood that the features of the various embodiments described herein can be combined with one another, unless specifically indicated otherwise. Therefore, the following detailed description should not be considered in a restrictive sense, and the scope of the present invention is defined by the appended claims.

The terms “connected” and “coupled” are used here both as direct or indirect connection and direct or indirect coupling. In the figures, identical or similar elements are provided with correspondingly identical reference signs. Unless indicated otherwise, the use of the word “substantially” should be interpreted such that it includes an exact relationship, a precise state, an exact device, exact orientation and/or other features and deviations therefrom such as are understood by a person of average skill in the art, to the extent that such deviations do not significantly influence the methods and systems disclosed. In the entirety of the present disclosure, the use of the articles “a/an” and/or “the” to modify a noun can be understood such that it is used for the sake of simplicity and includes one or more than one of the modified noun, unless indicated otherwise. The terms “comprise”, “include” and “have” are intended to be inclusive and mean that there may be elements other than the elements listed.

FIG. 1 illustrates a plan view of a schematic light-emitting device 100 in accordance with various embodiments. The light-emitting device 100 comprises a multiplicity of light-emitting modules 120 on a first substrate 110.

The light-emitting modules 120 comprise in each case a multiplicity of light-emitting components arranged in a sparse array pattern on a second substrate, and comprise a common primary lens in each case for the multiplicity of light-emitting components, as is described more thoroughly below.

In this way, the light-emitting device 100 is adaptable for a multiplicity of applications. In addition, defective light-emitting modules 120 can be exchanged more easily in comparison with light-emitting components formed directly on the first substrate 110, and the maintenance of the light-emitting device 100 is thus simplified.

FIG. 1 illustrates a light-emitting device comprising three light-emitting modules 120. However, the light-emitting device 100 can comprise fewer light-emitting modules 120, e.g. two light-emitting modules 120. Furthermore, the light-emitting device 100 can also comprise more than three light-emitting modules 120. In particular, the quantity of light-emitting modules 120 can be dependent on the intended application of the light-emitting device 100. As an example, the light-emitting device 100, e.g. as a headlight in a motor vehicle, comprises approximately 2 to approximately 100 light-emitting modules 120. In other words, the light-emitting device 100, e.g. a headlight, comprises light-emitting modules 120 having light-emitting components arranged in a sparse array arrangement (also referred to as a matrix arrangement).

This has the advantage, for example, that the sparsely populated light-emitting modules 120 divide the heat propagation in the light-emitting device 100 among the second substrates. This can result in drastically reduced thermal resistances in the light-emitting device 100. The thermal management can be improved as a result.

Furthermore, the production yield for the light-emitting device 100 is increased by means of the modular arrangement.

Furthermore, the surface “footprint” is maintained in comparison with standard LED modules, but the use of a large number of small light-emitting components in the light-emitting modules drastically reduces the structural depth of the module and of the device.

A plurality of lighting functions can be combined or integrated in the light-emitting device 100 by the use of different groups of light-emitting modules 120, wherein each group can comprise the same type of light-emitting modules. The complexity of the lighting system, for example with regard to the cabling, of a vehicle can be reduced as a result. A secondary optical unit that is not connected to the light-emitting modules 120 is not absolutely necessary. Furthermore, an unprecedented freedom of design is achieved by the use of different module groups.

Owing to the reduced structural depth of the light-emitting device 100, in an automotive application as a headlight 100, an opening in the vehicle bodywork is not necessarily required in order to secure the headlight 100 to the vehicle bodywork, as a result of which the stability of the vehicle bodywork is increased.

In various embodiments, the light-emitting device can comprise two or more substrates, which can be configured in such a way that their light-emitting modules can be driven identically or independently of one another.

Illustratively, the light-emitting device in accordance with various embodiments can be for example a complete headlight/spotlight or a part thereof, for example apart from a package, cable and/or light-transmissive cover.

The light-emitting modules 120 can be in direct contact with one another (illustrated in FIG. 1). Alternatively or additionally, in the case of a portion of the light-emitting modules 120 of the plurality of light-emitting modules 120, a gap or spacing is formed between the nearest neighbor light-emitting modules 120.

The light-emitting modules 120 can be electrically connected to one another, e.g. in series and/or parallel connection, e.g. in order to realize a common lighting function, e.g. low beam or high beam in automotive applications. The electrical circuit of the first substrate can be simplified in this way.

Alternatively or additionally, light-emitting modules 120 are electrically insulated from one another. Independent driving of the insulated light-emitting modules 120 is made possible in this way. The independent driving of the individual light-emitting components enables an adaptive driving beam in the case of a light-emitting module 120 configured for high beam.

In various embodiments, the light-emitting modules 120 can have in plan view a triangular, quadrilateral (illustrated in FIG. 1) or polygonal shape, e.g. a hexagonal shape (illustrated in FIG. 4 and FIG. 5).

The first substrate 110 serves as a carrier element for electronic elements or layers, for example the multiplicity of light-emitting modules.

The first substrate 110 can also be referred to as a main board (or motherboard). The first substrate 110 can be a circuit board, for example a two-layered (for example flexible) or multilayered circuit board, or a metal-coated film.

In various embodiments, the first substrate 110 is an FR1, FR2, FR3, FR4, FR5, CEM1, CEM2, CEM3, CEM4 or CEM5 circuit board. The first substrate 110 can be translucent or transparent.

The first substrate 110 can comprise or be formed from glass, quartz and/or a semiconductor material or some other suitable material, for example. Furthermore, the first substrate 110 can comprise or be formed from a plastic film or a laminate comprising one or more plastic films.

The first substrate 110 comprises a Kapton film (polyimide, PI), a metal film or a PET film, for example.

By way of example, the first substrate 110 can comprise or be formed from a steel film, a plastic film or a laminate comprising one or more plastic films. The plastic can include or be formed from one or more polyolefins (e.g. high or low density polyethylene (PE) or polypropylene (PP)). Furthermore, the plastic can be polyvinyl chloride (PVC), polystyrene (PS), polyester and/or polycarbonate (PC), polyethylene terephthalate (PET), polyethersulfone (PES), PEEK, PTFE and/or polyethylene naphthalate (PEN).

The first substrate 110 can comprise or be formed from a metal, for example copper, silver, gold, platinum, iron, for example a metal compound, for example steel.

The first substrate 110 can be embodied as a metal film or metal-coated film. The first substrate 110 can comprise one or more of the materials mentioned above.

The first substrate 110 can be part of a mirror structure or form a part thereof. The first substrate 110 can comprise a mechanically stiff region and/or a mechanically flexible region or be embodied in this way.

In various embodiments, the first substrate 110 can be a metal-coated film. The metal-coated film comprises for example a metal layer on a plastic film described above. The metal layer can be embodied as an electrical conductor structure for connecting the light-emitting modules 120 to an electrical energy source, a heat sink (cooling element) or a heat-conducting structure and/or a hermetically sealed layer with respect to water and oxygen with respect to the plastic film and/or the light-emitting modules. The heat sink, the heat-conducting structure or the metal layer can be embodied such that they dissipate heat from the light-emitting modules, for example by virtue of the heat sink having a greater surface area, emissivity, a greater convection coefficient and/or a greater thermal conductivity than at least one light-emitting module 120 which is in thermal contact with the cooling element.

In various embodiments, the multiplicity of light-emitting modules 120 is electrically connected to the first substrate 110, e.g. to one or more electrically conductive lines of the first substrate 110. By way of example, the multiplicity of light-emitting modules 120 is operated and/or supplied with energy by a power source external to the light-emitting device, through the first substrate 110.

In various embodiments, the light-emitting modules 120 can be connected or secure to the first substrate 110 by a cohesive connection medium, for example an adhesive, e.g. an electrically conductive adhesive, and/or a soldered joint, e.g. solder beads of a reflow process; or by a force-locking and/or positively locking connection, for example a latching or clamping connection, for example a snap-lock, snap-on or click-on connection.

In various embodiments, the light-emitting device 100 comprises a driver circuit (also referred to as driver, control electronics or controller; see also FIG. 5) configured for driving at least some or all of the light-emitting modules 120 of the multiplicity of light-emitting modules 120. The driver circuit can be embodied as an integrated circuit (IC), e.g. as an application specific integrated circuit (ASIC). The driver circuit can be arranged partly or completely on the first substrate 110, in one or the multiplicity of light-emitting modules 120 and/or outside the first substrate 110, as is described more thoroughly below.

In various embodiments, the driver circuit for driving the light-emitting components of a light-emitting module is part of the respective light-emitting module or fitted thereto.

In various embodiments, the first substrate 110 contains a multiplicity of electrically conductive conductor tracks or lines, e.g. metal tracks. The conductor tracks are electrically conductively connected to the light-emitting modules 120. The substrate 110 can furthermore comprise contact areas, e.g. at an edge or a non-light-emitting location of the first substrate 110, for example the rear side. The contact areas are connected to conductor tracks. The contact areas can be exposed for connection to an external power source. Light-emitting components of the light-emitting modules can be connected to the power source in this way.

The contact areas can be configured e.g. as plugs, pins and/or a socket.

The first substrate 110 can comprise a contact area embodied as an anode contact for the light-emitting modules 120, and can comprise a contact area embodied as a cathode contact for the light-emitting modules 120.

In various embodiments, at least one light-emitting module 120 of the multiplicity of light-emitting modules 120 comprises a first group of light-emitting components. The light-emitting components of the first group are configured to realize a lighting function. The at least one light-emitting module furthermore comprises a second group of light-emitting components configured to realize a display function. The lighting function and display function are realized in each case by means of the light emitted by the light-emitting components of the first group and second group, respectively.

In various embodiments, the light-emitting device 100 comprises a first group of light-emitting modules 120 of the multiplicity of light-emitting modules 120. The light-emitting modules of the first group are configured to realize a lighting function. The light-emitting device 100 furthermore comprises a second group of light-emitting modules of the multiplicity of light-emitting modules. The light-emitting modules of the second group are configured to realize a display function. The lighting function and display function are realized in each case by means of the light emitted by the light-emitting modules of the first group and second group, respectively.

The light-emitting modules or light-emitting components of the first and second groups can optionally be operated in a first operating mode (lighting function) or a second operating mode (display function). In the first operating mode, the light-emitting modules of the first group are driven in such a way that at least one lighting function is realized by means of the emitted light of the light-emitting modules of the first group. In the second operating mode, the light-emitting modules of the second group are driven in such a way that at least one predefined information item is represented by means of the emitted light of the light-emitting modules of the second group. The predefined information is for example a logo, an image, state information and/or a symbol.

Illustratively, the number density of light-emitting modules or light-emitting components of the lighting function in the light-emitting device can be too low to realize a display function. In embodiments with display functions, the light-emitting device can therefore furthermore comprise a multiplicity of light-emitting modules or light-emitting components arranged between the light-emitting modules or light-emitting components for the lighting function. As a result, it is possible to realize a light-emitting device with a display function with an improved resolution. The light-emitting modules of the multiplicity of light-emitting modules can realize a lighting function or a display function or be provided specifically for the realization thereof.

In the first and second operating modes, the same or different light-emitting modules or light-emitting components of light-emitting modules can be driven. In other words: light-emitting modules or light-emitting components which are driven only in the first operating mode or which are driven only in the second operating mode can be provided in the light-emitting device.

In order that an observer is not dazzled and/or in order that an image that is output is recognizable, the intensity of the light of the display function can be very much lower than the intensity of the light of the lighting function. Therefore, the light-emitting components or light-emitting modules of the display function do not contribute or do not significantly contribute to the lighting function. By way of example, the light-emitting components in the first operating mode are switched off during the second operating mode or emit only a small quantity of light relative to the light emitted for the lighting function, for example for esthetic reasons.

Moreover, light-emitting modules or light-emitting components can be provided which are driven in the first operating mode and in the second operating mode and emit light in each case. The driving, for example the operating current or the operating voltage, can be mutually different in the first and second operating modes. In the second operating mode (display function), these light-emitting components can be driven for example in a dimmed manner, for example in a pulse-modulated manner (e.g. pulse amplitude modulation (PAM), pulse width modulation (PWM), pulse frequency modulation (PFM)), with a lower operating current and/or with a lower operating voltage.

This makes it possible that a light-emitting device, for example a vehicle headlight, can optionally be used for representing information or for lighting. However, the light-emitting device can also be configured such that it can be operated simultaneously or exclusively in the first and second operating mode. By way of example, light-emitting modules which are operated in the second operating mode can be operated as a kind of luminous passe-partout or luminous frame for light-emitting modules which are operated in the first operating mode. This has the effect that an optical contrast between luminous region and non-luminous region (of the light-emitting device) can be reduced.

In other words: in various embodiments, the light-emitting device 100 comprises a first group of light-emitting modules of the multiplicity of light-emitting modules. The light-emitting modules of the first group are configured to realize at least one first lighting function and/or one second lighting function. In this case, the second lighting function is different than the first lighting function. At least one light-emitting module of the first group is part of a second group of light-emitting modules. The light-emitting modules of the second group are configured to realize a display function. The lighting function and display function are realized in each case by means of the light emitted by the light-emitting modules of the first group and second group, respectively. In various embodiments, the light-emitting device 100 is thus a display, for example for displaying information, and/or a lighting device, for example for realizing a lighting function. In the first operating mode, the light-emitting device is operated by means of corresponding driving substantially as lighting, for example as a light-emitting device, a spotlight, or the like (lighting function). Lighting functions in the case of a vehicle headlight are for example low beam, daytime running light, turning light, cornering light, fog lamp, adaptive driving beam, brake light, high beam, etc.

In the second operating mode, the light-emitting device is operated by means of corresponding driving substantially as a display device for displaying image data, video data or optical design elements (display function), for example as a display for representing logos, symbols, pictograms, text, video data and/or as an illuminated frame of the lighting function.

In various embodiments, at least some of the light-emitting modules of the second group (of the display function) are arranged between light-emitting modules of the first group. In other words, the light-emitting modules and the light-emitting modules of the second operating mode can be arranged in a manner spatially interposed or interleaved with respect to one another, for example in a similar manner to a checkered pattern, wherein a regular arrangement is optional.

In various embodiments, at least some of the light-emitting modules of the second group (of the display function) differ from the light-emitting modules of the first group (lighting function) in at least one of the following properties: a larger number of light-emitting components, a larger number density of light-emitting components and/or a simpler lens system, preferably no or only one lens.

FIG. 2 illustrates a plan view of a schematic light-emitting module 120 of a multiplicity of light-emitting modules of a light-emitting device 100 in accordance with various embodiments. The light-emitting device 100 can be embodied in accordance with an embodiment described above. Each of the light-emitting modules 120 of the light-emitting device (see FIG. 1) comprises a multiplicity of light-emitting components 210 on a second substrate 200.

The multiplicity of light-emitting components 210 of a light-emitting module 120 are arranged in a sparse array arrangement (also referred to as a matrix arrangement) on the second substrate 200. A common (also referred to as split) primary lens for (all) light-emitting components 210 of a light-emitting module is arranged over the light-emitting components 210 of the respective light-emitting module 120, as is described even more thoroughly below.

In various embodiments, a light-emitting component 210 can be a light-emitting semiconductor component which emits electromagnetic radiation, e.g. an electromagnetic radiation emitting diode, an electromagnetic radiation emitting organic diode, an electromagnetic radiation emitting transistor or an electromagnetic radiation emitting organic transistor. In other words, the light-emitting component 210 can be embodied for example as a light-emitting diode (LED), as an organic light-emitting diode (OLED), as a light-emitting transistor or as an organic light-emitting transistor. In various embodiments, the light-emitting component can be part of an integrated circuit. Furthermore, the multiplicity of light-emitting components can be accommodated in a common package.

In various embodiments, light-emitting components 210 are provided which are embodied as a wired light-emitting diode, a surface mounted device (SMD) or a chip-on-board light-emitting diode (LED) on the second substrate 200.

A wired light-emitting diode can comprise a semiconductor chip which can provide electromagnetic radiation, such as e.g. an LED chip. In the context of this description, therefore, a semiconductor chip which can provide electromagnetic radiation can be understood as an LED chip. An SMD light-emitting diode can comprise an LED chip in a package. The package can be cohesively connected to the second substrate 200. A chip-on-board light-emitting diode can comprise an LED chip fixed on the second substrate 200, wherein the LED chip can comprise neither a package nor a contact.

The light-emitting components emit an electromagnetic radiation which can be, comprise or encompass light in the visible range, ultraviolet (UV) light and/or infrared (IR) light.

A light-emitting diode as light-emitting component can be part of an integrated circuit. In accordance with various embodiments a light-emitting component can comprise a semiconductor chip (wired LED, SMD) which provides electromagnetic radiation, or can be configured as a semiconductor chip which provides electromagnetic radiation (chip-on-board). Alternatively or additionally, the light-emitting components 210 can be embodied directly on the second substrate 200.

Furthermore, a package can be embodied on or over the light-emitting components 210 of a light-emitting module 120. The package can for example be embodied as or comprise encapsulation, reflective layer structure, common primary lens, secondary lens and/or converter element.

FIG. 2 illustrates a light-emitting module 120 having four light-emitting components 210. However, each light-emitting module 120 can comprise fewer light-emitting components 210, e.g. two or three light-emitting components 210. Furthermore, each light-emitting module 120 can also comprise more than four light-emitting components 210. In particular, the quantity of light-emitting components 210 can depend on the intended application of the light-emitting device 100, e.g. a desired luminance, heat dissipation within a light-emitting module, etc.

As an example, the light-emitting device 100 used as a headlight in an automobile or as a spotlight can comprise approximately 50 to approximately 200 light-emitting modules having in each case approximately 2 to 20 light emitting devices 210 per light-emitting module 120.

In various embodiments, the light-emitting modules 120 comprise a matrix (also referred to as an array arrangement) having positions (entries or elements of the matrix) in which a light-emitting component 210 can be arranged in each case.

In various embodiments, a position of the matrix can be formed or defined by contacts. By way of example, positions are defined by contact locations or (ends of) conductor tracks on the second substrate 200 on which light-emitting components can be arranged in order to occupy a position of the matrix.

However, only some of all the possible positions of the matrix are occupied by light-emitting components 210. That is to say that some positions 220 of the matrix are free of light-emitting components 210. The matrix or array arrangement is thus only partly occupied by light-emitting components 210.

The matrix arrangement defined by all possible positions takes up only a small proportion of a surface area of the second substrate; by way of example, the area proportion of the surface area of the light-emitting module that is taken up by all the light-emitting components is less than 5%, for example less than 2.5%, for example less than 1%. In other words: the second substrate 200 is sparsely populated with light-emitting components 210.

As an example, the anode and cathode conductor tracks of the positions 220 that are free of light-emitting components 210 can be free ends, for example as stubs (or tap lines)—but without the purpose of forming a resonant circuit as in RF circuits. In contrast thereto, at positions of the matrix that are occupied by a light-emitting device 210, an anode conductor track on or in the second substrate 200 is connected to the anode contact of a light-emitting component 210, and a cathode conductor track on or in the second substrate 200 is connected to the cathode contact of the light-emitting component 210.

In this way, a sparse array arrangement of light-emitting components 210 is realized and the light-emitting components 210 are arranged in a sparse arrangement pattern or a sparse array arrangement.

In other words: each light-emitting module 120 has predetermined positions (elements or entries of a matrix) on which light-emitting devices 210 can be arranged, e.g. an M×N matrix, where N is greater than or equal to M. In various embodiments, N can be a number between 1 and 20, e.g. between 5 and 10, and M can be a number between 1 and 10, for example between 2 and 4.

If the light-emitting device is intended to be used to image a far field with an LED matrix, for example, said far field should have no illumination gaps. This is only able to be realized, however, if the light-emitting components also form a gapless array. A gapless arrangement of light-emitting components is often not possible physically (in terms of component mounting technology). The arrangement of the light-emitting components in the M×N matrix makes it possible that positions can be left free and nevertheless application-specifically different arrangements of light-emitting components are possible. In terms of component mounting technology, for example, in each case at least one matrix position which is free of light-emitting components can be arranged between closest adjacent light-emitting components. In the sum total of the illumination this enables an image as if a single, large area would be luminous.

In various embodiments, each light-emitting module 120 comprises a 1×N or 2×N matrix, where N is greater than or equal to 2. In various embodiments, N can be a number between 2 and 20, e.g. between 5 and 10.

The imaging of the emitted light that is emitted by the multiplicity of light-emitting components 210 of a light-emitting module through the common primary lens can be simplified by means of an M×N matrix.

In various embodiments, the light-emitting components of light-emitting modules can have a common electrical contact, e.g. a common anode conductor track.

The light-emitting components 210 can be in physically direct contact with one another.

In various embodiments, however, at least the nearest neighbor position of the matrix of possible positions is free of light-emitting components 210. In other words: in various embodiments maximally every second position is occupied by a light-emitting component 210. Consequently, maximally half of the positions of the matrix can be occupied by light-emitting components 210. The positioning of the light-emitting components 210 on the second substrate 200 is simplified in this way.

In other words: a gap (spacing) can be formed between the light-emitting components 120 of the multiplicity of light-emitting components.

The light-emitting components 210 can be electrically connected to one another, e.g. in series and/or parallel connection, e.g. in order to realize a common lighting function, e.g. low beam, instances of near field lighting; or instances of far or far field lighting in automotive applications. As an alternative thereto, the light-emitting components 210 are electrically insulated from one another. Independent driving of the light-emitting components 210 is made possible in this way.

In various embodiments, the light-emitting components 210 can have a circular (or point-like), triangular, quadrilateral or polygonal shape in plan view.

The light-emitting components 210 can have for example an edge length in the range of approximately 5 μm to approximately 300 μm.

The second substrate 200 can also be referred to as a daughterboard. In other words: the light-emitting device can comprise a multiplicity of daughterboards 200 arranged on a single/common motherboard or main board 100. The second substrate 200 can be a circuit board, e.g. in accordance with an above-described embodiment of the first substrate 100.

In various embodiments, the multiplicity of light-emitting components 210 is electrically connected to the second substrate 200, for example to one or more conductor tracks or conductor structures of the second substrate 200. The multiplicity of light-emitting components 210 can be connected to a power source external to the light-emitting device and be supplied with energy and/or operated by way of the electrically conductive structures, conductor tracks and connection of the first and second substrates 110, 200.

In various embodiments, the light-emitting components 210 can be connected to the second substrate 200 by a cohesive connection medium, for example an adhesive, e.g. an electrically conductive adhesive, and/or a soldered joint, e.g. solder beads of a reflow process. Alternatively or additionally, the light-emitting components 210 are embodied directly on the second substrate 200.

In various embodiments, the conductor tracks for contacting the light-emitting components are arranged on the top side of the second substrate, on which the light-emitting components are arranged. The conductor tracks can be embodied as an area and can be configured for heat dissipation, for example cooling, of the light-emitting components. Contact pads for the electrical connection between first substrate and light-emitting module, for example for driving the light-emitting components, can be arranged on the underside of the second substrate, opposite the top side. A further large or areal cooling area, for example embedded metallic coating, can be provided in the second substrate, for example embedded in the second substrate.

In various embodiments, the driver circuit or a part thereof, e.g. an IC or ASIC, of the light-emitting components of at least one light-emitting module is arranged on the second substrate 200 of a light-emitting module 120.

In various embodiments, the second substrate 200 comprises a multiplicity of conductor tracks as part of a circuit board, e.g. metal tracks. The conductive lines are electrically conductively connected to the light-emitting components 210. The second substrate 200 can furthermore comprise contact areas, e.g. at a non-light-emitting rear side of the second substrate 200. The contact areas can be or have been connected to the lines or conductor tracks of the first and second substrates. The conductor tracks of the light-emitting modules 120 can be embodied on the same side (top side) and/or the opposite side (rear side) of the second substrate 200, on which the light-emitting components 210 are arranged. The conductor tracks of the light-emitting modules 120 can be embodied in an areal manner. That is to say that the conductor tracks can substantially cover the surface area of the second substrate 200 or cover a significant portion of the upper surface area of the second substrate (e.g. more than approximately 50% of the upper surface area). In this way, the conductive lines can be used as efficient heat sinks. In other words: conductor tracks for contacting the light-emitting components 210 can be embodied with greater area than would be necessary purely for transporting current and, as a result, can act as cooling elements for the light-emitting components 210.

FIG. 3 illustrates a cross-sectional view of a schematic light-emitting module 120 of a multiplicity of light-emitting modules of a light-emitting device 100 in accordance with various embodiments.

The light-emitting device 100 and the light-emitting module (the light-emitting modules) 120 can be embodied in accordance with an embodiment described above.

FIG. 3 furthermore illustrates a reflective layer structure 320 and a common primary lens 300 for the light-emitting components 210 of a (single) light-emitting module 120, as described above.

The reflective layer structure 320 has an opening (illustrated as a white region in FIG. 3) in which the multiplicity of light-emitting components 210 are arranged such that they are surrounded or embedded in the sparse array arrangement as described above.

In other words, the reflective layer structure 320 is arranged such that it is aligned (aligned exactly or precisely) with respect to the light-emitting components 210 on the second substrate 200.

The light-emitting components 210 can emit light in a direction laterally and in relation to the surface of the second substrate 200, on which the light-emitting components 210 are arranged. The reflective layer structure 320 is configured to reflect this emitted light. As an example, the reflective layer structure 320 can be formed from a specularly reflective or diffusively reflective material, e.g. a ceramic, a TiO2 or Al2O3, or a white plastic or a white potting material (e.g. TiO2-filled silicone); or a metal, e.g. Al, Ag or Au.

The reflective layer structure 320 can be electrically insulating, e.g. a ceramic, or electrically conductive, e.g. Al, Ag, Au. In the case of an electrically conductive reflective layer structure 320, the reflective layer structure 320 can be electrically insulated from the conductive lines on the second substrate 200.

The common primary lens 300 for (all) light-emitting components 210 of a light-emitting module is formed over the light-emitting components 210 of the respective light-emitting module 120. In various embodiments, a variety of beam-shaping, optical components such as, for example, lenses or reflectors are represented on the basis of the example of the common primary lens 300. In other words, a corresponding common reflector for beam shaping could alternatively also be used instead of a common primary lens 300.

The common primary lens 300 is configured to image the light emitted by the multiplicity of light-emitting components 210, for example onto a common real or virtual focal point. Further optical elements can be arranged downstream of the common primary lens 300. A light-emitting module can comprise a single lens (common primary lens 300) or a lens system (common primary lens 300+secondary lens). In other words: in various embodiments, the light-emitting modules 120 comprise only one lens (primary lens 300) or a plurality of lenses (primary lens 300+additional lens(es), for example secondary lens) as beam-shaping optical elements. In other embodiments, however, the light-emitting modules 120 can also comprise at least one beam-shaping device instead of or in addition to the common primary lens 300, such as e.g. a reflector, a diffusing layer or a light-transmissive cover.

In various embodiments, the common primary lens 300 for the multiplicity of light-emitting components 210 of a light-emitting module 120 can be formed from a plastic, for example a polycarbonate (PC), a polysiloxane (silicone, for example PMMS or PDMS), a polyacrylate (for example PMMA).

It goes without saying that the type of primary lens 300 can be application-specific, e.g. a condenser lens, a diverging lens, a Fresnel lens, a cylindrical lens, an astigmatic lens or some other conventional lens, for example in order to form an individual light beam that is emitted or formed by the multiplicity of light-emitting components 210 of a light-emitting module 120.

In other words, the configuration of the common primary lens 300, e.g. the curvature, e.g. the imaging of the common primary lens 300, can depend on the desired application of the light-emitting device.

As an example, a first group of light-emitting modules can be used to realize near field light or low beam of a vehicle headlight, and a second group of light-emitting modules can be used to realize a different optical function of this vehicle headlight, e.g. far field, high beam, direction indicator, etc. The common primary lens of the module/modules in the first group of light-emitting modules can be configured differently than the common primary lens of the module/modules in the second group, e.g. with regard to curvature, focal length, etc. of the respective common primary lens. In addition, the light-emitting modules of the first and second groups can comprise different quantities of light-emitting components 210. As an example, a larger quantity of light-emitting components may be needed to realize high beam or far field and to realize a direction indicator or low beam. Consequently, the common primary lens of the light-emitting modules of the first and second groups can be adapted in order to image the light of the different sizes and arrangements of light-emitting components 210.

In various embodiments, the reflective layer structure 320 can comprise a connection structure 330, e.g. a multiplicity of openings 330 (e.g. two, three or more openings) configured to form a connection to the primary lens 300. Alternatively or additionally, the primary lens 300 can comprise a connection structure 310, e.g. a multiplicity of posts or projecting sections 310 (e.g. two, three or more posts) configured to form a connection to the reflective layer structure 320 and/or the second substrate 200.

In various embodiments, the connection structure 310 of the primary lens 300 and the connection structure 330 of the reflective layer structure 320 can be configured to form a positively locking or force-locking connection between the primary lens 300 and the reflective layer structure 320; for example, the connection structures 310, 330 can be configured in complementary fashion (illustrated by the arrows in FIG. 3). In this way, the alignment of the primary lens 300 can be simplified since the reflective layer structure 320 has already been aligned with regard to the light-emitting components 210.

Alternatively, the second substrate 200 can comprise a connection structure configured for forming a connection, e.g. a positively locking connection or force-locking connection, e.g. holes, to the connection structure 310 of the primary lens 300.

The light-emitting module 120 can furthermore comprise a package, e.g. in the form of a hollow cylinder or a cup-type cover, configured to accommodate or laterally enclose the common primary lens 300 and optionally other optical elements.

In addition, the package can also act as an aperture or a collimator for the light emitted by the light-emitting components 210.

The primary lens 300 can be secured to the second substrate 200 or the reflective layer structure 320 by an adhesion layer. Alternatively or additionally, the common primary lens can be secured to the second substrate 200 or the reflective layer structure 320 by a positively locking or force-locking connection to the package, which is secured to the second substrate 200 or the reflective layer structure 320 by an adhesive.

In various embodiments, the light-emitting module 120 furthermore comprises a shutter structure 340. The shutter structure 340 is arranged between the second substrate 200 and the common primary lens 300. The shutter structure 340 is arranged between the light-emitting components 210 for example, and is at least partly surrounded by the reflective layer structure 320. The shutter structure 340 is formed for example from a material having a high absorptance (for example greater than 90%) and a low reflectance (for example less than 10%) for the electromagnetic radiation that can be emitted by the light-emitting components. This has the effect that the shutter structure 340 reduces imaging aberrations owing to scattered light from the light-emitting components 210 and/or the common primary lens 300. This furthermore enables a sharp (stepped) contrast edge at the light-emitting components 210.

In various embodiments, the shutter structure 340 is embodied such that it is not movable, for example as a coating.

The material of the shutter structure 340 is configured in such a way that it is stable vis-à-vis visibly blue light and is stable vis-à-vis the thermal loading resulting from the absorption of the electromagnetic radiation.

The shutter structure 340 is formed from a metal sheet or a silicone, for example. The shutter structure 340 can be adhesively bonded on the second substrate 200 by means of an adhesive. Alternatively or additionally, the shutter structure 140 is fixed in a positively locking manner and/or in a force-locking manner between the second substrate 200 and the common primary lens 300. Alternatively or additionally, the shutter structure 340 is embodied directly on the second substrate 200, for example wet-chemically, for example by means of a spraying method.

The shutter structure 340 is embodied in a comb-shaped fashion, for example, wherein the light-emitting components 210 are arranged between the prongs of the comb-shaped shutter structure 340.

In various embodiments, the shutter structure 340 is configured as a spacer for arranging the common primary lens 300 over the second substrate 200, for example with regard to the height and the hardness of the shutter structure. This makes it possible that an undesirably inclined arrangement of the common primary lens 300 over the second substrate 200 can be prevented. The shutter structure 340 has for example a height in a range of approximately 5 μm to approximately 250 μm, for example in a range of approximately 10 μm to approximately 100 μm, for example in a range of approximately 20 μm to approximately 50 μm, for example approximately 40 μm.

FIG. 4 shows a plan view and FIG. 5 shows a bottom view of a schematic light-emitting device 100 comprising a plurality of light-emitting modules 120 in accordance with various embodiments.

The light-emitting device 100 can be embodied in accordance with an embodiment described above. In the embodiment illustrated, the light-emitting modules 120 have a hexagonal shape and thus enable dense packing of light-emitting modules 120.

The light-emitting modules 120 can be arranged in a cluster (compact arrangement) on the first substrate 110. The position of each light-emitting module can depend on the intended application of the light-emitting device 100 and the specific configuration of the individual light-emitting module 120, e.g. the number of light-emitting components. Different lighting patterns, functions or scenarios can be realized in this way.

In various embodiments, as illustrated in FIG. 5, a driver circuit 500, e.g. one or more ICs, configured for driving one, a plurality or all of the light-emitting modules 120 of the multiplicity of light-emitting modules 120 is arranged on a lower or rear side of the first substrate 110 and is connected to one or more light-emitting modules directly or indirectly (e.g. in the case of a series connection of modules).

The driver circuit 500 described herein is not restricted to a specific hardware or software configuration and can find application in many computer or processing environments. The driver circuit 500 can be implemented in hardware or software or a combination of hardware and software. The driver circuit 500 can be implemented in one or more computer programs, wherein a computer program can be understood such that it contains one or more processor-executable instructions. The computer program/computer programs can be executed on one or more programmable processors and can be stored on one or more processor-readable storage media (including volatile and nonvolatile memories and/or storage elements), one or more input devices, and/or one or more output devices. The processor can thus access one or more input devices in order to obtain input data, and can access one or more output devices in order to communicate output data.

In various embodiments, the light-emitting modules 120 can be arranged in a common plane, e.g. on a planar surface of the first substrate 100. Alternatively or additionally, the light-emitting modules 120 are arranged or can be arranged in different directions or in coplanar planes. For example, the first substrate and/or the second substrate can be (partly) deformable or movable, e.g. by one or more piezo drive(s). Consequently, a curvature or quasi-three-dimensional surface of the first substrate can be realized and a quasi-three-dimensional alignment of the light-emitting modules can be realized.

Although the light-emitting device, the light-emitting modules and the light-emitting components have been described with respect to embodiments, they are not restricted thereto. It is evident that many modifications and variations will become apparent in light of the above teachings. Many additional changes in the details, materials and the arrangement of parts which are described and illustrated herein can be undertaken by persons skilled in the art in this field. The invention is not restricted to the embodiments specified.

Embodiment 1 is a light-emitting device, comprising a multiplicity of light-emitting modules arranged on a first substrate. Each light-emitting module of the multiplicity of light-emitting modules comprises a multiplicity of light-emitting components arranged on a second substrate, wherein the second substrate is electrically connected to the first substrate; and a common primary lens for the multiplicity of light-emitting components.

In embodiment 2, the light-emitting device of embodiment 1 furthermore comprises the fact that the first substrate is a circuit board having electrically conductive lines, wherein the second substrates are connected to the electrically conductive lines of the first substrate.

In embodiment 3, the light-emitting device of embodiment 1 or 2 furthermore comprises the fact that the first substrate is configured such that it has a variable or changeable shape, such that the alignment of the second substrates is adjustable.

In embodiment 4, the light-emitting device of any of the preceding embodiments furthermore comprises the fact that the second substrate is a printed circuit board.

In embodiment 5, the light-emitting device in accordance with any of the preceding embodiments furthermore comprises the fact that the light-emitting components are arranged in a sparse array pattern on the second substrate.

In embodiment 6, the light-emitting device in accordance with any of the preceding embodiments furthermore comprises the fact that in at least some of the light-emitting modules of the multiplicity of light-emitting modules, in each case the light-emitting components are arranged in a single series.

In embodiment 7, the light-emitting device in accordance with any of embodiments 1 to 6 furthermore comprises the fact that in at least some of the light-emitting modules of the multiplicity of light-emitting modules, in each case the light-emitting components are arranged in two adjacent series.

In embodiment 8, the light-emitting device in accordance with any of the preceding embodiments furthermore comprises the fact that the multiplicity of light-emitting modules comprises at least one first group of modules configured to provide a first lighting function, and comprises a second group of modules configured to provide a second lighting function, which is different than the first lighting function.

In embodiment 9, the light-emitting device in accordance with embodiment 8 furthermore comprises the fact that the first group of modules differs from the second group of modules in at least one from the type of light-emitting components, the number of light-emitting components and the common primary lens.

In embodiment 10, the light-emitting device in accordance with embodiment 8 or 9 furthermore comprises the fact that the light-emitting device is a vehicle headlight and the first and second lighting functions are at least one from high beam, low beam, flashing indicator, cornering light and adaptive driving beam, fog light, brake light, position light.

In embodiment 11, the light-emitting device in accordance with any of the preceding embodiments furthermore comprises the fact that the light-emitting components of the light-emitting module are in each case of the same type.

In embodiment 12, the light-emitting device in accordance with any of the preceding embodiments furthermore comprises the fact that the common primary lens has a common or approximately common focal point for the light-emitting components.

In embodiment 13, the light-emitting device in accordance with any of the preceding embodiments furthermore comprises a secondary lens configured for correcting aberrations, and the common primary lens is arranged between the secondary lens and the light-emitting components.

In embodiment 14, the light-emitting device in accordance with any of the preceding embodiments furthermore comprises the fact that each of the light-emitting modules has a reflective layer structure configured such that it surrounds or embeds the multiplicity of light-emitting components, and configured such that it has a reflectivity of at least 80% with respect to incident light emitted by light-emitting components.

In embodiment 15, the light-emitting device in accordance with embodiment 14 furthermore comprises the fact that the reflective layer structure and/or the common primary lens comprise(s) a connection structure configured to secure the common primary lens to the reflective layer structure in a positively locking manner and/or in a force-locking manner.

In embodiment 16, the device in accordance with any of the preceding embodiments furthermore comprises the fact that each light-emitting module furthermore comprises a package fitted to the second substrate and configured to accommodate or (laterally) enclose the common primary lens.

In embodiment 17, the light-emitting device in accordance with any of the preceding embodiments furthermore comprises a driver circuit configured to drive at least one light-emitting module of the multiplicity of light-emitting modules. The driver circuit can be arranged on the first substrate or the second substrate of the driven light-emitting module.

In embodiment 18, the light-emitting device in accordance with embodiment 17 furthermore comprises the fact that the driver circuit is embodied in an integrated circuit.

In embodiment 19, the light-emitting device in accordance with embodiment 17 or 18 furthermore comprises the fact that light-emitting modules are arranged by their rear side on a front side of the first substrate and the driver circuit is arranged on a rear side of the first substrate or a rear side of a second substrate.

In embodiment 20, the light-emitting device in accordance with any of the preceding embodiments furthermore comprises the fact that the first substrate comprises a continuous electrical connection structure configured to connect the multiplicity of light-emitting modules by way of the continuous electrical connection structure to a power source external to the light-emitting device, by way of a single connector, for example plug.

Embodiment 21 is a method for producing a light-emitting device, wherein the method comprises providing a first substrate and arranging a multiplicity of light-emitting modules on the first substrate. Each light-emitting module of the multiplicity of light-emitting modules comprises a multiplicity of light-emitting components arranged on a second substrate, wherein the second substrate is electrically connected to the first substrate; and a common primary lens for the multiplicity of light-emitting components.

In embodiment 22, the method of embodiment 21 furthermore comprises the fact that the first substrate is a circuit board having electrically conductive lines, wherein the second substrates are connected to electrically conductive lines of the first substrate.

In embodiment 23, the method of embodiment 21 or 22 furthermore comprises the fact that the first substrate is configured such that it has a changeable shape, and so the alignment of the second substrates is adjustable.

In embodiment 24, the method in accordance with any of the preceding embodiments furthermore comprises the fact that the second substrate is a circuit board.

In embodiment 25, the method in accordance with any of the preceding embodiments furthermore comprises the fact that the light-emitting components are arranged in each case in a sparse array arrangement on the second substrate.

In embodiment 26, the method in accordance with any of the preceding embodiments furthermore comprises the fact that in at least some of the light-emitting modules of the multiplicity of light-emitting modules, in each case the light-emitting components are arranged in a single series.

In embodiment 27, the method in accordance with any of embodiments 21 to 26 furthermore comprises the fact that in at least some of the light-emitting modules of the multiplicity of light-emitting modules, in each case the light-emitting components are arranged in two series.

In embodiment 28, the method in accordance with any of the preceding embodiments furthermore comprises the fact that the multiplicity of light-emitting modules comprises at least one first group of modules configured to provide a first lighting function, and comprises a second group of modules configured to provide a second lighting function, which is different than the first lighting function.

In embodiment 29, the method in accordance with embodiment 28 furthermore comprises the fact that the first group of modules differs from the second group of modules in at least one from the type of light-emitting components, the number of light-emitting components and the common primary lens.

In embodiment 30, the method in accordance with embodiment 28 or 29 furthermore comprises the fact that the light-emitting device is a vehicle headlight and the first and second lighting functions are at least one from high beam, low beam, flashing indicator, cornering light and adaptive driving beam, fog light, brake light, position light.

In embodiment 31, the method in accordance with any of the preceding embodiments furthermore comprises the fact that the light-emitting components of the light-emitting module are in each case of the same type.

In embodiment 32, the method in accordance with any of the preceding embodiments furthermore comprises the fact that the common primary lens has a common or approximately common focal point for the light-emitting components.

In embodiment 33, the method in accordance with any of the preceding embodiments furthermore comprises a secondary lens configured for correcting aberrations, and the common primary lens is arranged between the secondary lens and the light-emitting components.

In embodiment 34, the method in accordance with any of the preceding embodiments furthermore comprises the fact that each of the light-emitting modules comprises a reflective layer structure configured such that it surrounds or embeds the multiplicity of light-emitting components, and configured such that it has a reflectivity of at least 80% with respect to incident light emitted by light-emitting components.

In embodiment 35, the method in accordance with embodiment 34 furthermore comprises the fact that the reflective layer structure and/or the common primary lens comprise(s) a connection structure configured to secure the common primary lens to the reflective layer structure in a positively locking manner and/or in a force-locking manner.

In embodiment 36, the method in accordance with any of the preceding embodiments furthermore comprises the fact that each light-emitting module furthermore comprises a package fitted to the second substrate and configured to accommodate or (laterally) enclose the common primary lens.

In embodiment 37, the method according to any of the following preceding furthermore comprises forming a driver circuit configured to drive at least one light-emitting module of the multiplicity of light-emitting modules. The driver circuit can be formed on the first substrate or the second substrate of the driven light-emitting module.

In embodiment 38, the method in accordance with embodiment 37 furthermore comprises the fact that the driver circuit is embodied in an integrated circuit.

In embodiment 39, the method in accordance with embodiment 37 or 38 furthermore comprises the fact that the light-emitting modules are arranged by their rear side on a front side of the first substrate and the driver circuit is arranged on a rear side of the first substrate or a rear side of a second substrate.

In embodiment 40, the method in accordance with any of the preceding embodiments furthermore comprises the fact that the first substrate comprises a continuous electrical connection structure configured to connect the multiplicity of light-emitting modules by way of the continuous electrical connection structure to a power source external to the light-emitting device, by way of a single connector, for example plug.

In embodiment 41, at least one light-emitting module of the multiplicity of light-emitting modules according to any of the preceding embodiments comprises a first group of light-emitting components configured to realize a lighting function by means of the light emitted by the light-emitting components of the first group, and a second group of light-emitting components configured to realize a display function by means of the light emitted by the light-emitting components of the second group.

In embodiment 42, the light-emitting device according to any of the preceding embodiments furthermore comprises a first group of light-emitting modules of the multiplicity of light-emitting modules, configured to realize a lighting function by means of the light emitted by the light-emitting modules of the first group, and a second group of light-emitting modules of the multiplicity of light-emitting modules, configured to realize a display function by means of the light emitted by the light-emitting modules of the second group.

In embodiment 43, the light-emitting device according to embodiment 42 comprises the fact that at least some of the light-emitting modules of the second group are arranged between light-emitting modules of the first group, and wherein at least some of the light-emitting modules of the second group differ from the light-emitting modules of the first group in at least one property from the group: a larger number of light-emitting components, a larger number density of light-emitting components and/or a simpler lens system, preferably no or only one lens.

In embodiment 44, the light-emitting device according to any of the preceding embodiments comprises a first group of light-emitting modules of the multiplicity of light-emitting modules, configured to realize at least one first lighting function and/or a second lighting function different than the first lighting function, by means of the light emitted by the light-emitting modules of the first group, and comprises the fact that at least one light-emitting module of the first group is part of a second group of light-emitting modules configured to realize a display function by means of the light emitted by the light-emitting modules of the second group.

Embodiment 45 is a method for operating a light-emitting device 100 with a lighting function and a display function in accordance with any of embodiments 41 to 44, wherein, in a first operating mode, the light-emitting modules or light-emitting components of the first group are driven in such a way that at least one lighting function is realized by means of the emitted light of the light-emitting modules or of the light-emitting components of the first group, and, in a second operating mode, the light-emitting modules or light-emitting components of the second group are driven in such a way that at least one predefined information item, preferably a logo, an image, state information and/or a symbol, is represented by means of the emitted light of the light-emitting modules or of the light-emitting components of the second group.

Although the exemplary aspects of the present disclosure have been described in detail with reference to the accompanying drawings, the present disclosure is not restricted thereto and can be implemented in many different forms, without departing from the technical concept of the present disclosure. Therefore, the exemplary aspects of the present disclosure are provided only for illustration purposes, but are not intended to restrict the scope of the technical concept of the present disclosure. Therefore, it should be understood that the exemplary aspects described above are illustrative in all aspects and do not restrict the present disclosure. The scope of protection of the present disclosure should be interpreted on the basis of the following claims.

### LIST OF REFERENCE SIGNS

100 light-emitting device

110 first substrate

120 light-emitting module

200 second substrate

210 light-emitting component

220 position free of light-emitting component

300 common primary lens

310, 330 connection structure

320 reflective layer structure

340 shutter structure

500 driver circuit

1. A light-emitting device, comprising:
multiplicity of light-emitting modules arranged on a first substrate, wherein each light-emitting module of the multiplicity of light-emitting modules comprises:
multiplicity of light-emitting components arranged on a second substrate, wherein the second substrate is electrically connected to the first substrate; and
common primary lens for the multiplicity of light-emitting components.

2. The light-emitting device as claimed in claim 1, wherein the first substrate is a circuit board having electrically conductive lines, wherein the second substrates are electrically conductively connected to the conductive lines of the first substrate.

3. The light-emitting device as claimed in claim 1, wherein the first substrate is configured such that it has a variable shape, and so the orientation of the second substrates is adjustable.

4. The light-emitting device as claimed in claim 1, wherein the second substrate is a printed circuit board.

5. The light-emitting device as claimed in claim 1, wherein the light-emitting components are arranged in each case in a sparse array pattern on the second substrate.

6. The light-emitting device as claimed in claim 1, wherein, in at least some of the light-emitting modules of the multiplicity of light-emitting modules, the light-emitting components are arranged in each case in two directly adjacent series on the second substrate.

7. The light-emitting device as claimed in claim 1, wherein the multiplicity of light-emitting modules comprises at least one first group of modules configured to provide a first lighting function by means of the light emitted by the light-emitting modules of the first group, and comprises a second group of modules configured to provide a second lighting function, which differs from the first lighting function, by means of the light emitted by the light-emitting modules of the second group.

8. The light-emitting device as claimed in claim 1, wherein at least one light-emitting module of the multiplicity of light-emitting modules comprises a first group of light-emitting components configured to realize a lighting function by means of the light emitted by the light-emitting components of the first group, and a second group of light-emitting components configured to realize a display function by means of the light emitted by the light-emitting components of the second group.

9. The light-emitting device as claimed in claim 1, furthermore comprising:
a first group of light-emitting modules of the multiplicity of light-emitting modules, configured to realize a lighting function by means of the light emitted by the light-emitting modules of the first group, and a second group of light-emitting modules of the multiplicity of light-emitting modules, configured to realize a display function by means of the light emitted by the light-emitting modules of the second group.

10. The light-emitting device as claimed in claim 9,
wherein at least some of the light-emitting modules of the second group are arranged between light-emitting modules of the first group, and
wherein at least some of the light-emitting modules of the second group differ from the light-emitting modules of the first group in at least one property from the group: a larger number of light-emitting components, a larger number density of light-emitting components and/or a simpler lens system, preferably no or only one lens.

11. The light-emitting device as claimed in claim 1, furthermore comprising:
a first group of light-emitting modules of the multiplicity of light-emitting modules, configured to realize at least one first lighting function and/or a second lighting function different than the first lighting function, by means of the light emitted by the light-emitting modules of the first group, and
wherein at least one light-emitting module of the first group is part of a second group of light-emitting modules configured to realize a display function by means of the light emitted by the light-emitting modules of the second group.

12. The light-emitting device as claimed in claim 1,
wherein the light-emitting components of the light-emitting module are of the same type.

13. The light-emitting device as claimed in claim 1,
wherein the common primary lens has a common or approximately common focal point for the light-emitting components.

14. The light-emitting device as claimed in claim 1,
wherein each of the light-emitting modules comprises a reflective layer structure configured to surround or to embed the multiplicity of light-emitting components and configured such that it has a reflectivity of at least 80% with regard to the incident light emitted by the light-emitting components; and
wherein the reflective layer structure and/or the common primary lens comprise(s) a connection structure configured to secure the common primary lens to the reflective layer structure.

15. The light-emitting device as claimed in claim 1, furthermore comprising: a driver circuit configured to drive at least one light-emitting module of the multiplicity of light-emitting modules, wherein the driver circuit is arranged on the first substrate or the second substrate of the driven light-emitting module.

16. The light-emitting device as claimed in claim 1, wherein the driver circuit is embodied in an integrated circuit.

17. The light-emitting device as claimed in claim 1, wherein light-emitting modules are arranged by their rear side on a front side of the first substrate and the driver circuit is arranged on a rear side of the first substrate or a rear side of a second substrate.

18. The light-emitting device as claimed in claim 1, wherein the first substrate comprises a continuous electrical connection structure configured to connect the multiplicity of light-emitting modules by way of the continuous electrical connection structure to a power source external to the light-emitting device, by way of a single plug.

19. A method for producing a light-emitting device, wherein the method comprises:
providing a first substrate and arranging a multiplicity of light-emitting modules on the first substrate, wherein each light-emitting module of the multiplicity of light-emitting modules comprises:
multiplicity of light-emitting components arranged on a second substrate, wherein the second substrate is electrically connected to the first substrate; and
common primary lens for the multiplicity of light-emitting components.

20. A method for operating a light-emitting device with a lighting function and a display function as claimed in claim 8,
wherein, in a first operating mode, the light-emitting modules or light-emitting components of the first group are driven in such a way that at least one lighting function is realized by means of the emitted light of the light-emitting modules or of the light-emitting components of the first group, and, in a second operating mode, the light-emitting modules or light-emitting components of the second group are driven in such a way that at least one predefined information item, preferably a logo, an image, state information and/or a symbol, is represented by means of the emitted light of the light-emitting modules or of the light-emitting components of the second group.
